(19) United States
(12) Patent Application Publication
(10) Pub. No.: US 2026/0172065 A1
(43) Pub. Date: Jun. 18, 2026

(54) FILTER CIRCUIT AND COMMUNICATION DEVICE

(71) Applicant: Kabushiki Kaisha Toshiba, Tokyo (JP)

(72) Inventors: Tamio KAWAGUCHI, Yokohama Kanagawa (JP); Hiroaki IKEUCHI, Yokohama Kanagawa (JP)

(21) Appl. No.: 19/257,035

(22) Filed: Jul. 1, 2025

(30) Foreign Application Priority Data
Dec. 18, 2024 (JP) 2024-221387

(51) Int. Cl. H04B 1/10; H03H 1/00

(52) U.S. Cl. CPC H04B 1/10; H03H 1/0007

(57) ABSTRACT

According to one embodiment, a filter circuit includes first and second terminals, and a filter element. The filter element includes a transmission line, coupling transmission lines including first and second transmission lines, and resonant elements including first and second resonant elements. The first resonant element resonates at a first frequency. The second resonant element resonates at a second frequency. The intermediate portion has electrical length θc1 at a first center frequency being ½ a sum of the first frequency and the second frequency. The first transmission line has a first electrical length θ1 at the first center frequency. The second transmission line has a second electrical length θ2 at the first center frequency. A first sum of the first intermediate portion electrical length θc1, the first electrical length θ1, and the second electrical length θ2 is substantially (2n+1)×90 degrees. n is an integer equal to or greater than 0.

### CROSS-REFERENCE TO RELATED APPLICATIONS

This application is based upon and claims the benefit of priority from Japanese Patent Application No. 2024-221387, filed on Dec. 18, 2024; the entire contents of which are incorporated herein by reference.

### FIELD

Embodiments described herein relate generally to a filter circuit and a communication device.

### BACKGROUND

For example, filter circuits are used in high-frequency circuits. There is a demand for improved characteristics of the filter circuits.

### BRIEF DESCRIPTION OF THE DRAWINGS

FIG. 1 is a schematic diagram illustrating a filter circuit according to a first embodiment;

FIG. 2 is a schematic diagram illustrating a filter circuit of a reference example;

FIGS. 3A and 3B are graphs illustrating the characteristics of the filter circuit of the reference example;

FIGS. 4A and 4B are graphs illustrating the characteristics of the filter circuit according to the first embodiment;

FIGS. 5A and 5B are schematic views illustrating a filter circuit according to the first embodiment;

FIG. 6 is a schematic plan view illustrating a filter circuit according to the first embodiment;

FIG. 7 is a schematic plan view illustrating a filter circuit according to the first embodiment;

FIG. 8 is a schematic plan view illustrating a filter circuit according to the first embodiment;

FIG. 9 is a schematic plan view illustrating a filter circuit according to the first embodiment;

FIG. 10 is a schematic diagram illustrating a filter circuit according to the first embodiment;

FIG. 11 is a schematic plan view illustrating a filter circuit according to the first embodiment;

FIG. 12 is a graph illustrating a filter circuit according to the first embodiment;

FIG. 13 is a schematic diagram illustrating a filter circuit according to the first embodiment;

FIG. 14 is a schematic diagram illustrating a filter circuit according to the first embodiment;

FIG. 15 is a schematic diagram illustrating a filter circuit according to the first embodiment;

FIG. 16 is a schematic diagram illustrating a filter circuit according to the first embodiment;

FIG. 17 is a schematic diagram illustrating a filter circuit according to the first embodiment;

FIG. 18 is a schematic diagram illustrating a filter circuit according to the first embodiment;

FIG. 19 is a graph illustrating the characteristics of the filter according to the first embodiment;

FIG. 20 is a schematic diagram illustrating a filter circuit according to the first embodiment; and

FIG. 21 is a schematic diagram illustrating a communication device according to a second embodiment.

### DETAILED DESCRIPTION

According to one embodiment, a filter circuit includes a first terminal, a second terminal, and a filter element. The filter element includes a transmission line, a plurality of coupling transmission lines including a first transmission line and a second transmission line, and a plurality of resonant elements including a first resonant element and a second resonant element. The transmission line includes an input portion configured to be coupled to the first terminal, an output portion configured to be coupled to the second terminal, and an intermediate portion between the input portion and the output portion. A first portion of the first transmission line is configured to be coupled with a first connection point between the input portion and the intermediate portion. A second portion of the second transmission line is configured to be coupled with a second connection point between the intermediate portion and the output portion. The first resonant element is configured to be coupled with a first other portion of the first transmission line. The second resonant element is configured to be coupled with a second other portion of the second transmission line. The first resonant element is configured to resonate at a first frequency. The second resonant element is configured to resonate at a second frequency. The intermediate portion has a first intermediate portion electrical length θc1 at a first center frequency being ½ a sum of the first frequency and the second frequency. The first transmission line has a first electrical length θ1 at the first center frequency. The second transmission line has a second electrical length θ2 at the first center frequency. A first sum of the first intermediate portion electrical length θc1, the first electrical length θ1, and the second electrical length θ2 is substantially (2n+1)×90 degrees. n is an integer equal to or greater than 0.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

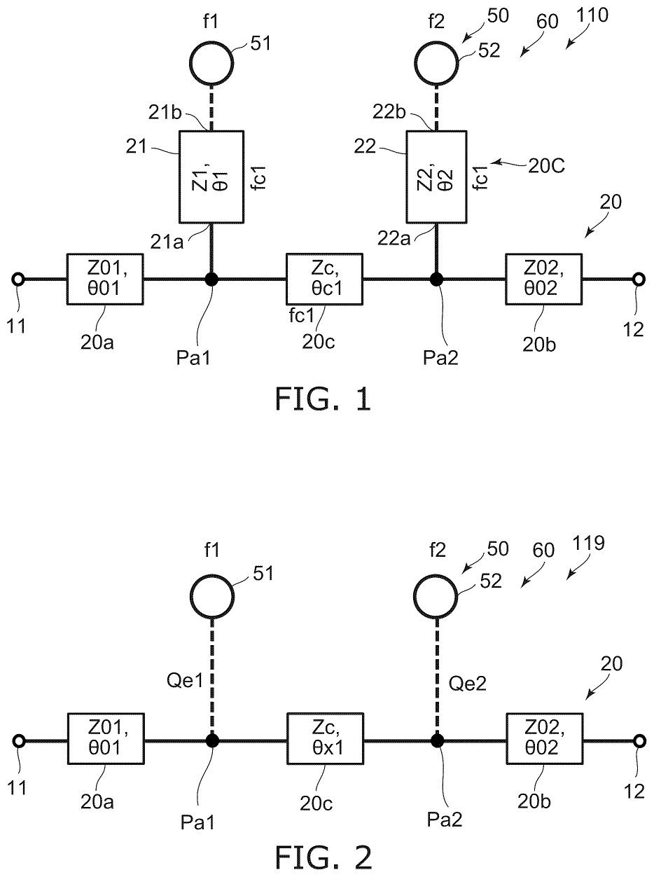

FIG. 1 is a schematic diagram illustrating a filter circuit according to a first embodiment.

As shown in FIG. 1, a filter circuit 110 according to the embodiment includes a first terminal 11, a second terminal 12, and a filter element 60. For example, a signal is input to the first terminal 11. The first terminal 11 is configured to receive the input signal. The second terminal 12 is configured to output a signal. For example, the first terminal 11 is an input terminal. The second terminal 12 is an output terminal.

The filter element 60 includes a transmission line 20, a plurality of coupling transmission lines 20C, and a plurality of resonant elements 50. The plurality of coupling transmission lines 20C include, for example, a first transmission line 21 and a second transmission line 22. The plurality of resonant elements 50 include, for example, a first resonant element 51 and a second resonant element 52.

The transmission line 20 includes an input portion 20a, an output portion 20b, and an intermediate portion 20c. The input portion 20a is configured to be coupled to the first terminal 11. The output portion 20b is configured to be coupled to the second terminal 12. The intermediate portion 20c is located between the input portion 20a and the output portion 20b.

A first portion 21a of the first transmission line 21 is configured to be coupled with a first connection point Pa1 between the input portion 20a and the intermediate portion 20c. A second portion 22a of the second transmission line 22 is configured to be coupled with a second connection point Pa2 between the intermediate portion 20c and the output portion 20b. The first transmission line 21 may be directly connected to the input portion 20a and the intermediate portion 20c at the first connection point Pa1. The second transmission line 22 may be directly connected to the output portion 20b and the intermediate portion 20c at the second connection point Pa2. The first resonant element 51 is configured to be coupled with the first other portion 21b of the first transmission line 21. The second resonant element 52 is configured to be coupled with the second other portion 22b of the second transmission line 22.

The first resonant element 51 is configured to resonate at a first frequency f1. The second resonant element 52 is configured to resonate at a second frequency f2. The first frequency f1 may be the same as the second frequency f2. The first frequency f1 may be different from the second frequency f2.

The intermediate portion 20c has a first intermediate portion electrical length θc1 at a first center frequency fc1 that is ½ the sum of the first frequency f1 and the second frequency f2. The first transmission line 21 has a first electrical length θ1 at the first center frequency fc1. The second transmission line 22 has a second electrical length θ2 at the first center frequency fc1.

In the embodiment, a sum (first sum) of the first intermediate portion electrical length θc1, the first electrical length θ1, and the second electrical length θ2 is substantially (2n+1)×90 degrees. “n” is an integer equal to or greater than 0.

For example, the characteristics of the first resonant element 51 and the second resonant element 52 are synthesized via the first transmission line 21, the intermediate portion 20c, and the second transmission line 22. The electrical path length between the first resonant element 51 and the second resonant element 52 is set to be substantially an odd multiple of 90 degrees. As a result, good attenuation characteristics are effectively obtained in a band including the first frequency f1 and the second frequency f2.

In the embodiment, the path between the two resonant elements 50 is separated into three portions (the first transmission line 21, the intermediate portion 20c, and the second transmission line 22). The three portions can be easily set independently of one another. Each of these portions can be set, for example, to make the circuit size compact. By separating them into three, for example, there is a high degree of freedom in the installation position of each of the plurality of resonant elements 50.

In the embodiment, for example, it is easy to design the first transmission line 21 and the second transmission line 22 so that the overall size of the circuit is small. For example, by providing the first transmission line 21 and the second transmission line 22, the electrical length of the intermediate portion 20c can be shortened. This makes it possible to suppress loss in the intermediate portion 20c for signals in the passband passing through the input/output terminals. By shortening the electrical length of the intermediate portion 20c, for example, the overall size of the circuit can be reduced. The desired filter characteristics can be obtained in a small size. For example, pass loss can be reduced in a small size. According to the embodiment, a filter circuit with improved characteristics can be provided.

For example, the deviation of the first sum from (2n+1)×90 degrees may be, for example, about ±20% or less. For example, the absolute value of the difference between the first sum and (2n+1)×90 degrees may be 20 degrees or less.

The filter circuit 110 may have a target band that is a target. The target band may correspond, for example, to an attenuation band. The target band may correspond, for example, to a stop band. At least a part of the band except for the target band corresponds to a pass band. The filter circuit 110 is, for example, a band-stop filter.

The first frequency f1 and the second frequency f2 are not less than a lower limit frequency and not more than an upper limit frequency of the target band.

In the filter circuit 110, the input portion 20a has an input portion electrical length θ01. The output portion 20b has an output portion electrical length θ02. These electrical lengths may be set arbitrarily.

In the filter circuit 110, the first transmission line 21 has a first characteristic impedance Z1. The second transmission line 22 has a second characteristic impedance Z2. The intermediate portion 20c has an intermediate portion characteristic impedance Zc. The input portion 20a has an input portion impedance Z01. The output portion 20b has an output portion impedance Z02. In the embodiment, these characteristic impedances may be set arbitrarily. The input portion impedance Z01 may be, for example, 50 Ω. The output portion impedance Z02 may be, for example, 50 Ω.

In the embodiment, “coupling” includes coupling by an electromagnetic field. “Coupling” may include coupling based on a capacitance or an inductor. “Coupling” may include, for example, coupling using a ¼ wavelength impedance converter.

FIG. 2 is a schematic diagram illustrating a filter circuit of a reference example.

As shown in FIG. 2, in a filter circuit 119 of a reference example, the first transmission line 21 and the second transmission line 22 are not provided. In the filter circuit 119, the first resonant element 51 is coupled with the first connection point Pa1 without passing through the first transmission line 21. The second resonant element 52 is coupled with the second connection point Pa2 without passing through the second transmission line 22.

In the filter circuit 119, the electrical length of the intermediate portion 20c at the first center frequency fc1, which is ½ the sum of the first frequency f1 and the second frequency f2, is the electrical length θx1.

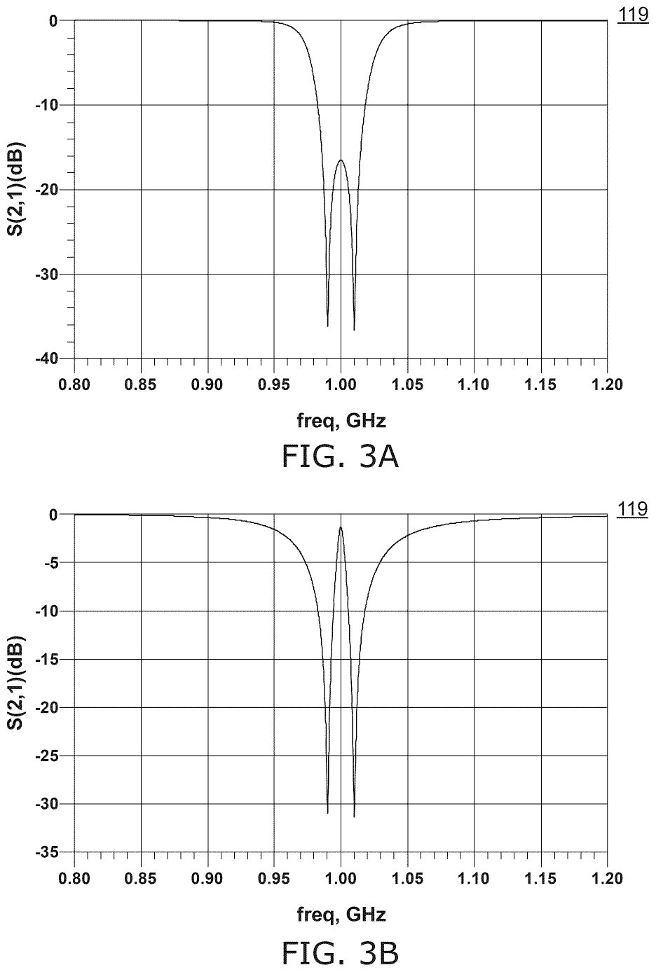

FIGS. 3A and 3B are graphs illustrating the characteristics of the filter circuit of the reference example.

The horizontal axis of these figures is frequency. The vertical axis is the transmission characteristic S(2,1). In FIG. 3A, the electrical length θx1 is 90 degrees. In FIG. 3B, the electrical length θx1 is 180 degrees. In these examples, the first frequency f1 is 1.01 GHz. The second frequency f2 is 0.99 GHz. The degree of coupling between the first resonant element 51 and the first connection point Pa1, and the degree of coupling between the second resonant element 52 and the second connection point Pa2 are each 30. This value is expressed as an external Q value.

As shown in FIG. 3A, in a case where the electrical length θx1 is 90 degrees, a stopband having a predetermined bandwidth is formed. This is due to the synthesis of reflected waves from the two resonant elements 50. In a case where the resonant frequencies of the two resonant elements 50 are the same, the stopband attenuation is increased. Thus, in a case where the plurality of resonant elements 50 are connected with an electrical length that is an odd multiple of 90 degrees, the desired attenuation and bandwidth can be obtained.

As shown in FIG. 3A, in a case where the electrical length θx1 is 180 degrees, the transmission amount is large at the intermediate frequency between the resonant frequencies of the two resonant elements 50, and practically no attenuation is obtained. In this case, two stop bands are formed independently by each of the two resonant elements 50. To obtain a band-stop filter with plurality of bands, the electrical length θx1 between the plurality of resonant elements 50 may be set to an integer multiple of 180 degrees.

As explained with reference to FIG. 3A and FIG. 3B, different band characteristics are obtained depending on the electrical length between the plurality of resonators. In a case where the electrical length between the plurality of resonators is an odd multiple of 90 degrees, a band-stop filter of one band is obtained. In a case where the electrical length between the plurality of resonators is an integer multiple of 180 degrees, a band-stop filter of plurality of bands is obtained.

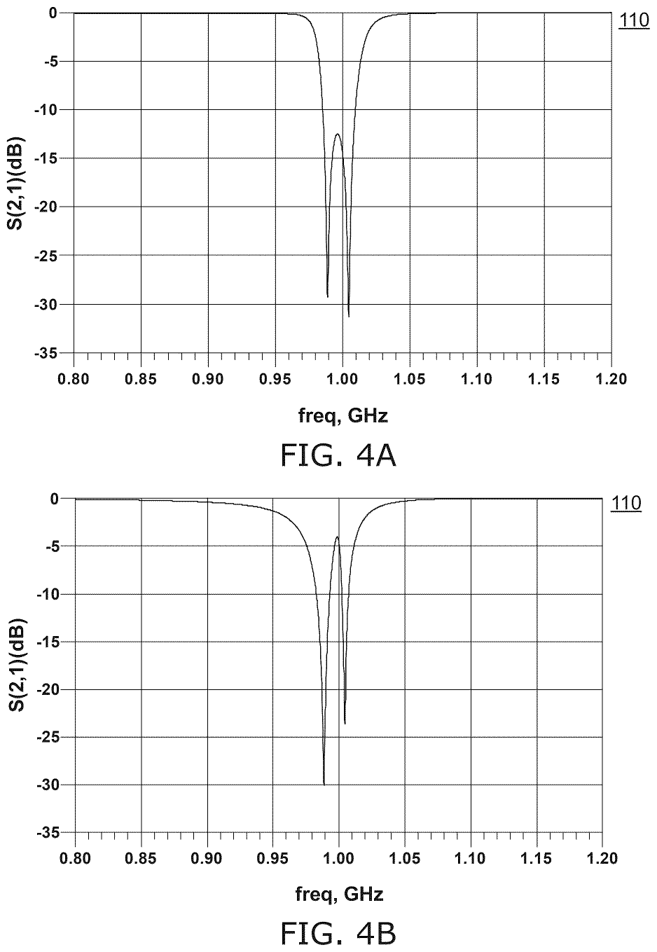

FIGS. 4A and 4B are graphs illustrating the characteristics of the filter circuit according to the first embodiment.

The horizontal axis of these figures is frequency. The vertical axis is the transmission characteristic S(2,1). In FIG. 4A, the first sum is 90 degrees. In FIG. 4B, the first sum is 180 degrees.

In the example shown in FIGS. 4A and 4B, the first frequency f1 is 0.992 GHz, and the second frequency f2 is 1.008 GHz. The degree of coupling between the two resonant elements 50 and the transmission line is 50. This value is expressed as the external Q value. The first characteristic impedance Z1, the second characteristic impedance Z2, the intermediate portion characteristic impedance Zc, the input portion impedance Z01, and the output portion impedance Z02 are 50 Ω.

In FIG. 4A, the first intermediate portion electrical length θc1 is 70 degrees. The first electrical length θ1 and the second electrical length θ2 are each 10 degrees. As shown in FIG. 4B, one stop band is obtained. The transmission loss in the passband is affected by the intermediate portion 20c. In a case where the first sum is an odd multiple of 90 degrees, in the embodiment, the first intermediate portion electrical length θc1 is shorter than the electrical length θx1 in the above reference example. In the embodiment, the transmission loss can be reduced.

In FIG. 4B, the first intermediate portion electrical length θc1 is 160 degrees. The first electrical length θ1 and the second electrical length θ2 are each 10 degrees. As shown in FIG. 4B, two stop bands are obtained. The transmission loss in the passband is affected by the intermediate portion 20c. Even in a case where the first sum is an integer multiple of 180 degrees, in the embodiment, the first intermediate portion electrical length θc1 is shorter than the electrical length θx1 in the above-mentioned reference example. In the embodiment, the insertion loss can be reduced.

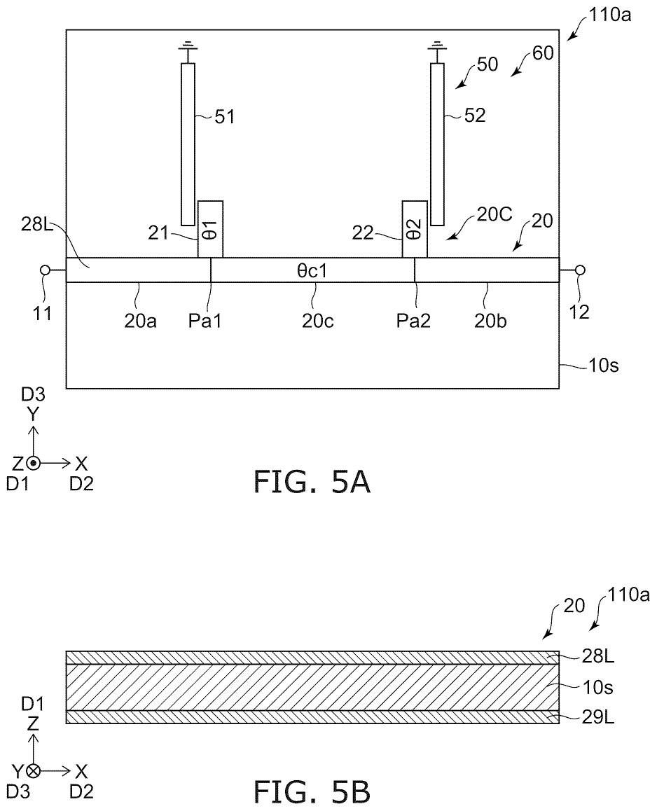

FIGS. 5A and 5B are schematic views illustrating a filter circuit according to the first embodiment.

FIG. 5A is a plan view. FIG. 5B is a cross-sectional view.

As illustrated in FIG. 5A, in a filter circuit 110a according to the embodiment, a microstrip line structure is applied. In the filter circuit 110a, the first electrical length θ1 and the second electrical length θ2 are each 10 degrees. The first intermediate electrical length θc1 is 70 degrees.

As shown in FIG. 5B, a base 10s is provided between a second conductive layer 29L and a first conductive layer 28L. Depending on the pattern shape of the first conductive layer 28L, the transmission line 20, the plurality of coupling transmission lines 20C, the plurality of resonant elements 50, and the like are formed. The second conductive layer 29L corresponds to, for example, a ground layer.

The base 10s may be insulating. The base 10s may include at least one of an inorganic material or an organic material. The base 10s may include, for example, a material used in flexible substrates (for example, polyimide or liquid crystal polymer material). The base 10s may include, for example, a glass cloth substrate, a fluororesin substrate, or a ceramic substrate. The ceramic substrate may include, for example, aluminum oxide.

The first conductive layer 28L and the second conductive layer 29L may include a metal. The metal may include at least one selected from the group consisting of gold and copper. These conductive layers may include at least one selected from the group consisting of aluminum, an alloy containing aluminum, niobium, an alloy containing niobium, tantalum, and an alloy containing tantalum. The alloy containing niobium may include niobium titanium. These conductive layers may include a superconducting material.

In the filter circuit 110a, the first resonant element 51 and the second resonant element 52 are ¼-wave resonators with one end grounded. The filter circuit 110a corresponds to a two-stage band-stop filter. One end of each of the first resonant element 51 and the second resonant element 52 is grounded. These one ends are electrically connected to the second conductive layer 29L.

The relative dielectric constant of the base 10s is, for example, 3.4. The thickness of the base 10s is, for example, 0.5 mm. In a case where the line width is 1.1 mm, the characteristic impedance is 50 Ω. In a case where the resonant frequency of the resonant element 50 is 1 GHz, the length of the conductive layer corresponding to the resonant element 50 is set to a length that is ¼ of the wavelength corresponding to the resonant frequency. For example, in a case where the frequency is 1 GHz, the length of the conductive layer (line length) is 45.9 mm.

In the embodiment, the elements included in the filter circuit may have various structures such as a coplanar structure, a waveguide, a strip line structure, or a coaxial structure in addition to a microstrip line structure.

In the example of the filter circuit 110a, the distance between the first resonant element 51 and the first transmission line 21 is short. The distance between the second resonant element 52 and the second transmission line 22 is short. Capacitive coupling is applied.

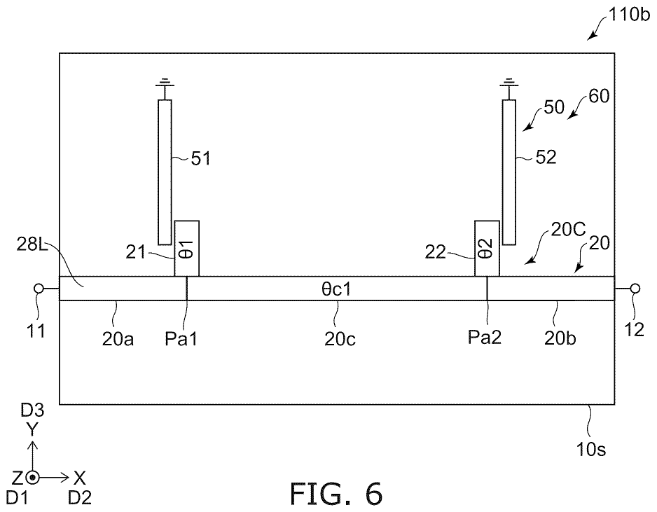

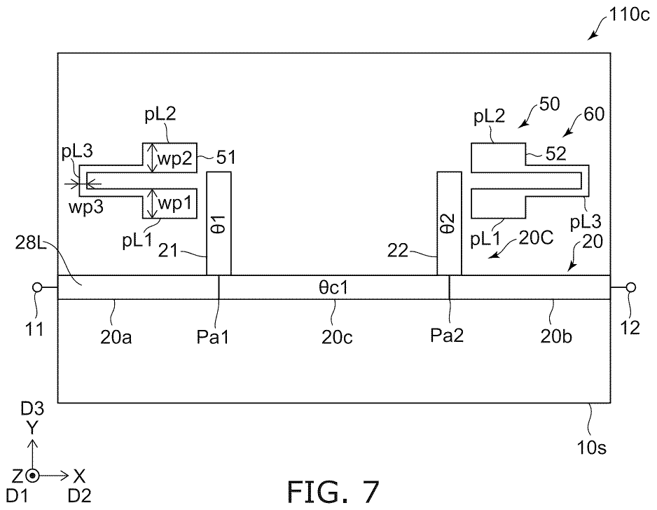

FIG. 6 is a schematic plan view illustrating a filter circuit according to the first embodiment.

As illustrated in FIG. 6, in a filter circuit 110b according to the embodiment, a microstrip line structure is applied. In the filter circuit 110b, the first electrical length θ1 and the second electrical length θ2 are each 10 degrees. The first intermediate electrical length θc1 is 160 degrees. The filter circuit 110b provides a stop filter including two bands.

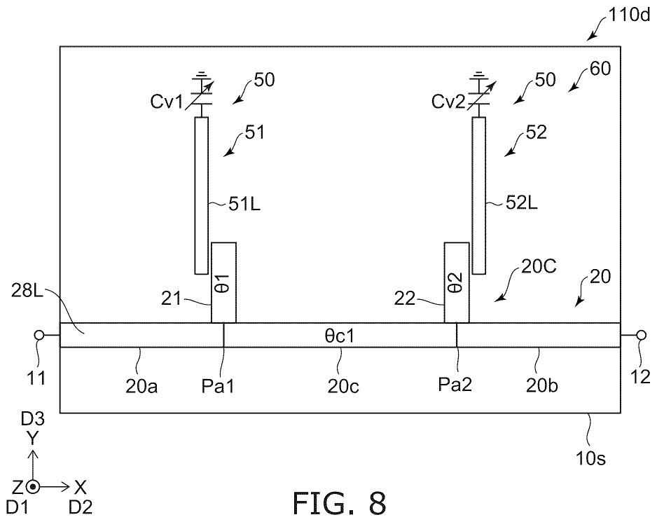

FIG. 7 is a schematic plan view illustrating a filter circuit according to the first embodiment.

In a filter circuit 110c according to the embodiment illustrated in FIG. 7, the first electrical length θ1 and the second electrical length θ2 are each 15 degrees. The first intermediate electrical length θc1 is 60 degrees. The filter circuit 110c is, for example, a two-stage band-stop filter.

In the filter circuit 110c, the first resonant element 51 and the second resonant element 52 are both open-ended resonators. A ½ wavelength stepped impedance resonant element is applied to each of the first resonant element 51 and the second resonant element 52. In the stepped impedance resonant element, the line width of the conductive layer that becomes the resonant element changes in a step shape. This allows the frequency of the high-order resonance to be shifted to a higher frequency.

In this example, the width of each of the two ends of the conductive layer that becomes the resonant element is wider than the width of the intermediate portion between the two ends. The line is bent so that the two ends approach each other. The parasitic capacitance between the two ends increases. This allows the resonant element to be made smaller. By increasing the impedance ratio between the thin line portion and the thick line portion, the high-order resonance can be shifted to a higher frequency side. This makes it easier to obtain a wide passband. A band-stop filter with wide band is obtained.

Thus, at least one of the first resonant element 51 and the second resonant element 52 may include a resonator with both ends open. The resonator with both ends open includes a first conductive portion pL1, a second conductive portion pL2, and a third conductive portion pL3. The third conductive portion pL3 is between the first conductive portion pL1 and the second conductive portion pL2. A third conductive portion line width wp3 of the third conductive portion pL3 is narrower than a first conductive portion line width wp1 of the first conductive portion pL1 and narrower than a second conductive portion line width wp2 of the second conductive portion pL2.

The distance between the first resonant element 51 and the first transmission line 21 is short. The distance between the second resonant element 52 and the second transmission line 22 is short. Capacitive coupling is applied.

FIG. 8 is a schematic plan view illustrating a filter circuit according to the first embodiment.

In the filter circuit 110d according to the embodiment illustrated in FIG. 8, the first electrical length θ1 and the second electrical length θ2 are each 10 degrees. The first intermediate electrical length θc1 is 70 degrees. The filter circuit 110d is, for example, a two-stage band-stop filter.

In the filter circuit 110d, a resonant element to which a distributed constant line and a variable capacitance element are applied is used for each of the first resonant element 51 and the second resonant element 52. For example, a variable capacitance element is connected to one end of a microstrip line. The capacitance can be changed by changing the bias voltage applied to the variable capacitance element. The resonant frequency can be changed by changing the capacitance.

For example, the first resonant element 51 includes a first element line 51L and a first variable capacitance element Cv1. One end of the first element line 51L is coupled with the first transmission line 21. The other end of the first element line 51L is connected to one end of the first variable capacitance element Cv1. The other end of the first variable capacitance element Cv1 is grounded.

For example, the second resonant element 52 includes a second element line 52L and a second variable capacitance element Cv2. One end of the second element line 52L is coupled with the second transmission line 22. The other end of the second element line 52L is connected to one end of the second variable capacitance element Cv2. The other end of the second variable capacitance element Cv2 is grounded.

Thus, at least one of the first resonant element 51 or the second resonant element 52 may include a frequency variable resonator 50v. One end of the frequency variable resonator 50v is grounded. A variable capacitance element (such as the first variable capacitance element Cv1) is connected to another end of the frequency variable resonator 50v. A bias circuit that applies a voltage to the variable capacitance element may be provided. The bias circuit may be included in the filter circuit 110d. The bias circuit may be provided separately from the filter circuit 110d.

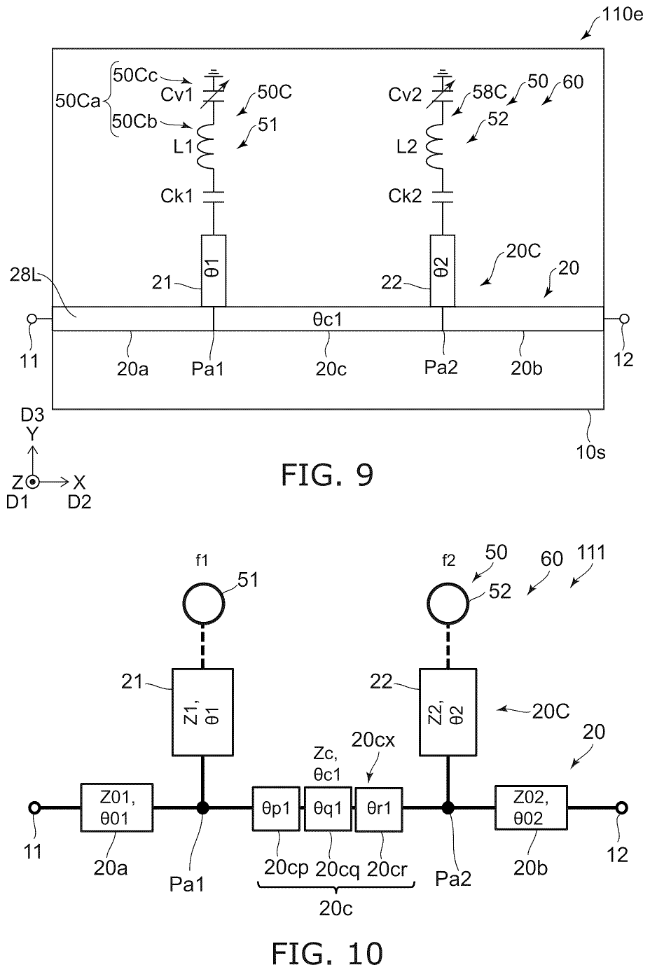

FIG. 9 is a schematic plan view illustrating a filter circuit according to the first embodiment.

In the filter circuit 110e according to the embodiment illustrated in FIG. 9, each of the first electrical length θ1 and the second electrical length θ2 is 10 degrees. The first intermediate portion electrical length θc1 is 70 degrees. The filter circuit 110e is, for example, a two-stage band-stop filter.

A variable capacitance element may be applied to the filter circuit 110e. This allows the resonant frequency to be changed.

For example, the first resonant element 51 includes a first inductor L1 and a first variable capacitance element Cv1. In this example, the first inductor L1 is connected in series with the first variable capacitance element Cv1. The first inductor L1 and the first variable capacitance element Cv1 correspond to an LC resonator. The first inductor L1 and the first variable capacitance element Cv1 may be connected in parallel. The LC resonator including the first inductor L1 and the first variable capacitance element Cv1 may be coupled with the first transmission line 21 by a first coupling capacitance element Ck1.

For example, the second resonant element 52 includes a second inductor L2 and a second variable capacitance element Cv2. In this example, the second inductor L2 is connected in series with the second variable capacitance element Cv2. The second inductor L2 and the second variable capacitance element Cv2 correspond to an LC resonator. The second inductor L2 and the second variable capacitance element Cv2 may be connected in parallel. The LC resonator including the second inductor L2 and the second variable capacitance element Cv2 may be coupled with the second transmission line 22 by a second coupling capacitance element Ck2.

In this way, at least one of the first resonant element 51 or the second resonant element 52 may include an LC resonator 50C. The LC resonator 50C includes a lumped element 50Ca. The lumped element 50Ca includes an inductive element 50Cb and a capacitive element 50Cc.

The first coupling capacitive element Ck1 and the second coupling capacitive element Ck2 may include, for example, a chip capacitor or a variable capacitive element. The first coupling capacitive element Ck1 and the second coupling capacitive element Ck2 may be, for example, a capacitor including two parallel electrodes.

In the filter circuit 110e, the LC resonator may be coupled with the transmission line by inductive coupling using an inductor element.

FIG. 10 is a schematic diagram illustrating a filter circuit according to the first embodiment.

As shown in FIG. 10, in a filter circuit 111 according to the embodiment, the intermediate portion 20c includes a plurality of partial intermediate portions 20cx. The configuration of the filter circuit 111 except for this may be the same as the configuration of the filter circuit 110.

In this example, the plurality of partial intermediate portions 20cx include a first partial intermediate portion 20cp, a second partial intermediate portion 20cq, and a third partial intermediate portion 20cr.

The first partial intermediate portion 20cp has a first partial intermediate portion electrical length θp1 at the first center frequency fc1. The second partial intermediate portion 20cq has a second partial intermediate portion electrical length θq1 at the first center frequency fc1. The third partial intermediate portion 20cr has a third partial intermediate portion electrical length θr1 at the first center frequency fc1.

The first intermediate portion electrical length θc1 is the sum of the first partial intermediate portion electrical length θp1, the second partial intermediate portion electrical length θq1, and the third partial intermediate portion electrical length θr1. Thus, the first intermediate portion electrical length θc1 is the total electrical length of the plurality of partial intermediate portions 20cx at the first center frequency fc1.

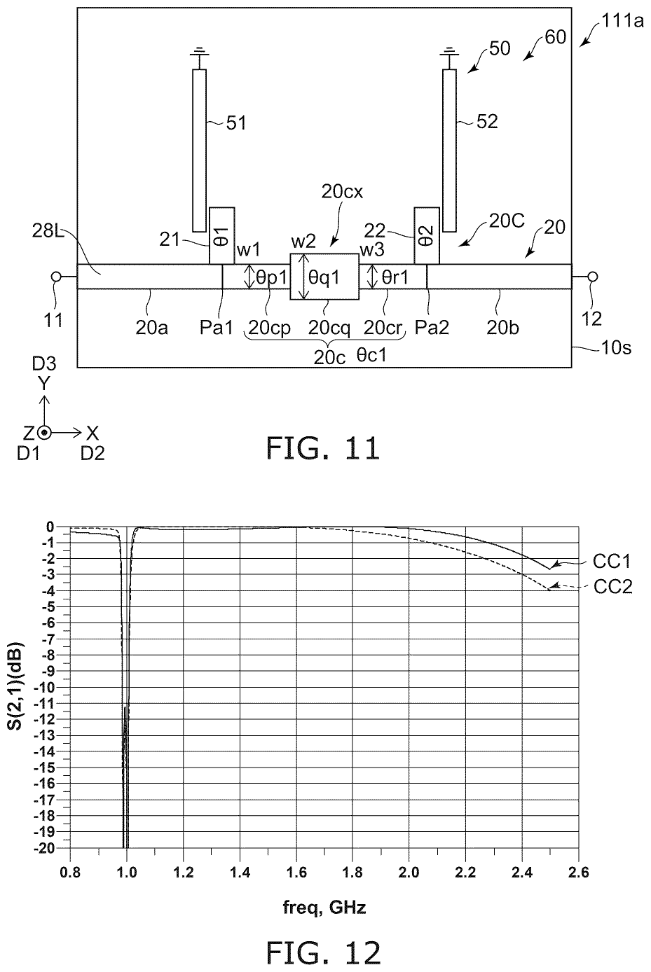

FIG. 11 is a schematic plan view illustrating a filter circuit according to the first embodiment.

As shown in FIG. 11, in a filter circuit 111a according to the embodiment, the intermediate portion 20c includes the plurality of partial intermediate portions 20cx. In this example, the plurality of partial intermediate portions 20cx include the first partial intermediate portion 20cp, the second partial intermediate portion 20cq, and the third partial intermediate portion 20cr.

The second partial intermediate portion 20cq is between the first partial intermediate portion 20cp and the third partial intermediate portion 20cr. A second line width w2 of the second partial intermediate portion 20cq is different from a first line width w1 of the first partial intermediate portion 20cp. The second line width w2 is different from a third line width w3 of the third partial intermediate portion 20cr. In this example, the second line width w2 is wider than the first line width w1 and wider than the third line width w3.

The line width changes discontinuously in the plurality of partial intermediate portions 20cx. The discontinuous change in line width causes a discontinuous change in the characteristic impedance.

For example, the characteristic impedance of the first partial intermediate portion 20cp is 50 Ω. The characteristic impedance of the second partial intermediate portion 20cq is 40 Ω. The characteristic impedance of the third partial intermediate portion 20cr is 50 Ω. The discontinuous change in the characteristic impedance can reduce losses, for example, as described below.

In the filter circuit 111a, the first partial intermediate portion electrical length θp1 is 12.5 degrees. The second partial intermediate portion electrical length θq1 is 45 degrees. The third partial intermediate portion electrical length θr1 is 12.5 degrees. The first intermediate portion electrical length θc1 is 70 degrees. Each of the first electrical length θ1 and the second electrical length θ2 is 10 degrees. The filter circuit 111a is, for example, a two-stage band-stop filter.

FIG. 12 is a graph illustrating a filter circuit according to the first embodiment.

The horizontal axis of FIG. 12 is frequency. The vertical axis is the transmission characteristic S(2,1) between the input terminal and the output terminal. FIG. 12 illustrates the characteristics of a first configuration CC1 and a second configuration CC2. In the first configuration CC1, the characteristic impedance of the first partial intermediate portion 20cp and the third partial intermediate portion 20cr is 50 Ω, and the characteristic impedance of the second partial intermediate portion 20cq is 40 Ω. In the second configuration CC2, the characteristic impedance of the first partial intermediate portion 20cp, the second partial intermediate portion 20cq and the third partial intermediate portion 20cr is 50 Ω. The first frequency f1 is 0.992 GHz, and the second frequency f2 is 1.008 GHz.

As shown in FIG. 12, in the first configuration CC1, compared to the second configuration CC2, the pass loss is improved outside the stopband, particularly on the high-frequency side. Thus, by the characteristic impedance being changed discontinuously, loss is reduced.

In the embodiment, the second line width w2 may be narrower than the first line width w1 and narrower than the third line width w3. In this case as well, loss can be reduced.

Thus, in the embodiment, the first line width w1 of one of the plurality of partial intermediate portions 20cx may be different from the second line width w2 of another one of the plurality of partial intermediate portions 20cx.

In the embodiment, the characteristic impedance of the second partial intermediate portion 20cq may be lower than the characteristic impedance of the first partial intermediate portion 20cp and lower than the characteristic impedance of the third partial intermediate portion 20cr. In the embodiment, the characteristic impedance of the second partial intermediate portion 20cq may be higher than the characteristic impedance of the first partial intermediate portion 20cp and higher than the characteristic impedance of the third partial intermediate portion 20cr. Loss can be reduced.

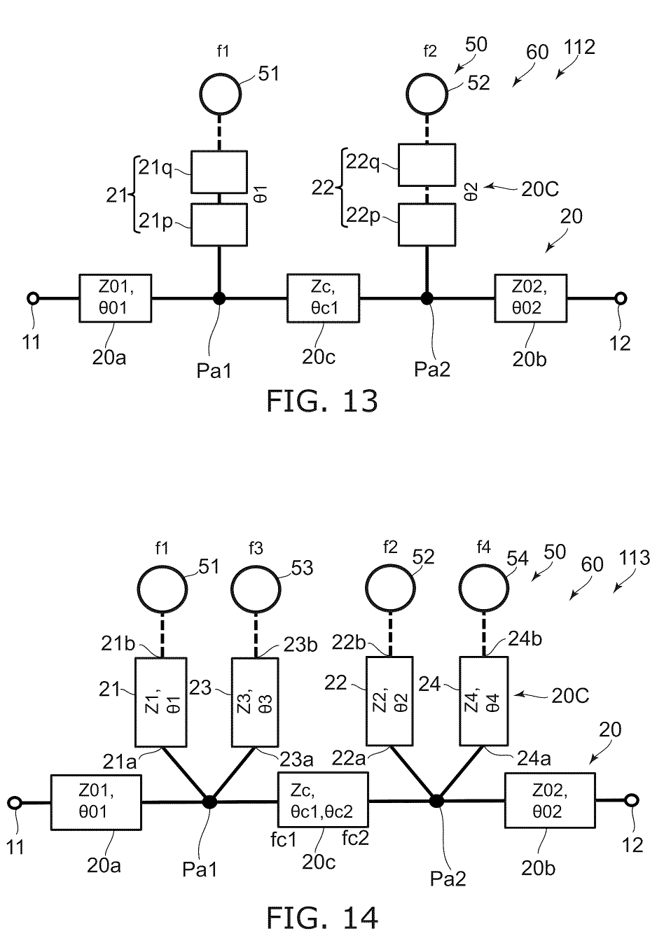

FIG. 13 is a schematic diagram illustrating a filter circuit according to the first embodiment.

As illustrated in FIG. 13, in a filter circuit 112 according to the embodiment, the first transmission line 21 includes plurality of portions, and the second transmission line 22 includes plurality of portions. The configuration of the filter circuit 112 except for this may be the same as the configuration of the filter circuit 110.

In the filter circuit 112, the first transmission line 21 includes a plurality of first partial transmission lines (such as transmission line 21p and transmission line 21q) configured to be coupled with each other. The second transmission line 22 includes a plurality of second partial transmission lines (such as transmission line 22p and transmission line 22q) configured to be coupled with each other.

The first electrical length θ1 is the total electrical length of the plurality of first partial transmission lines at the first center frequency fc1. The second electrical length θ2 is the total electrical length of the plurality of second partial transmission lines at the first center frequency fc1.

FIG. 14 is a schematic diagram illustrating a filter circuit according to the first embodiment.

As illustrated in FIG. 14, in a filter circuit 113 according to the embodiment, the plurality of coupling transmission lines 20C further include a third transmission line 23 and a fourth transmission line 24. The plurality of resonant elements 50 further include a third resonant element 53 and a fourth resonant element 54. The configuration of the filter circuit 113 except for these may be the same as the configuration of the filter circuit 110.

In the filter circuit 113, the third portion 23a of the third transmission line 23 is configured to be coupled with the first connection point Pa1. The fourth portion 24a of the fourth transmission line 24 is configured to be coupled with the second connection point Pa2. The third resonant element 53 is configured to be coupled with the third other portion 23b of the third transmission line 23. The fourth resonant element 54 is configured to be coupled with the fourth other portion 24b of the fourth transmission line 24.

The third resonant element 53 is configured to resonate at a third frequency f3. The fourth resonant element 54 is configured to resonate at a fourth frequency f4. The third frequency f3 and the fourth frequency f4 are not less than the lower limit frequency and not more than the upper limit frequency of the target band.

The intermediate portion 20c has a second intermediate portion electrical length θc2 at a second center frequency fc2 that is ½ the sum of the third frequency f3 and the fourth frequency f4. The third transmission line 23 has a third electrical length θ3 at the second center frequency fc2. The fourth transmission line 24 has a fourth electrical length θ4 at the second center frequency fc2.

In the embodiment, the second sum of the second intermediate portion electrical length θc2, the third electrical length θ3, and the fourth electrical length θ4 is (2m+1)×90 degrees. “m” is an integer equal to or greater than 0.

In a band including the third frequency f3 and the fourth frequency f4, good attenuation characteristics are effectively obtained. For example, there is a high degree of freedom in the positions of the third resonant element 53 and the fourth resonant element 54. The overall size of the circuit can be reduced. The electrical length of the intermediate portion 20c can be shortened. For example, the transmission loss can be reduced with a small size. A filter circuit with improved characteristics can be provided.

For example, a filter circuit including the first band including the first frequency f1 and the second frequency f2, and a second band including the third frequency f3 and the fourth frequency f4 is obtained. Signals are attenuated in the first band and the second band. The filter circuit 113 attenuates the components of the first band and the second band.

The third frequency f3 may be the same as the fourth frequency f4. The third frequency f3 may be different from the fourth frequency f4.

The third transmission line 23 has a third characteristic impedance Z3. The fourth transmission line 24 has a fourth characteristic impedance Z4. These characteristic impedances may be set arbitrarily.

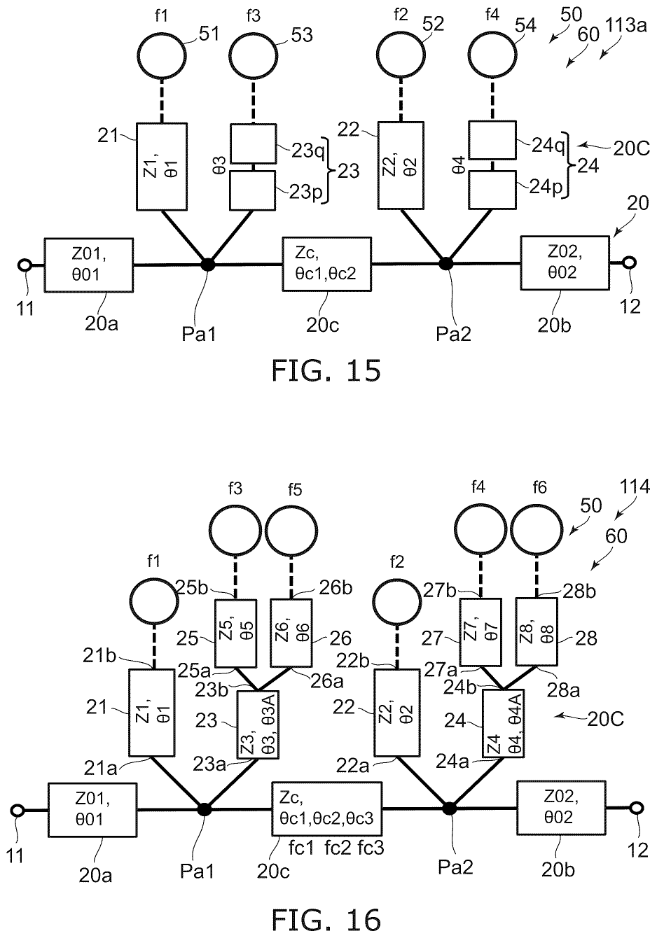

FIG. 15 is a schematic diagram illustrating a filter circuit according to the first embodiment.

As illustrated in FIG. 15, in a filter circuit 113a according to the embodiment, the third transmission line 23 includes plurality of portions, and the fourth transmission line 24 includes plurality of portions. The configuration of the filter circuit 113a except for these may be the same as the configuration of the filter circuit 113.

In the filter circuit 113a, the third transmission line 23 includes a plurality of third partial transmission lines (such as transmission line 23p and transmission line 23q) configured to be coupled with each other. The fourth transmission line 24 includes a plurality of fourth partial transmission lines (such as transmission line 24p and transmission line 24q) configured to be coupled with each other. The third electrical length θ3 is the total electrical length of the plurality of third partial transmission lines at the second center frequency fc2. The fourth electrical length θ4 is the total electrical length of the plurality of fourth partial transmission lines at the second center frequency fc2.

FIG. 16 is a schematic diagram illustrating a filter circuit according to the first embodiment.

As illustrated in FIG. 16, in a filter circuit 114 according to the embodiment, the plurality of coupling transmission lines 20C further include many transmission lines, and the plurality of resonant elements 50 further include many resonant elements 50. The configuration of the filter circuit 114 except for this may be the same as the configuration of the filter circuit 110, for example.

In the filter circuit 114, the plurality of coupling transmission lines 20C further include a third transmission line 23, a fourth transmission line 24, a fifth transmission line 25, a sixth transmission line 26, a seventh transmission line 27, and an eighth transmission line 28. The plurality of resonant elements 50 further include a third resonant element 53, a fourth resonant element 54, a fifth resonant element 55, and a sixth resonant element 56.

The third portion 23a of the third transmission line 23 is configured to be coupled with the first connection point Pa1. The fifth portion 25a of the fifth transmission line 25 is configured to be coupled with the third other portion 23b of the third transmission line 23. The sixth portion 26a of the sixth transmission line 26 is configured to be coupled with the third other portion 23b.

The fourth portion 24a of the fourth transmission line 24 is configured to be coupled with the second connection point Pa2. The seventh portion 27a of the seventh transmission line 27 is configured to be coupled with the fourth other portion 24b of the fourth transmission line 24. The eighth portion 28a of the eighth transmission line 28 is configured to be coupled with the fourth other portion 24b.

The third resonant element 53 is configured to be coupled with the fifth other portion 25b of the fifth transmission line 25. The fifth resonant element 55 is configured to be coupled with the sixth other portion 26b of the sixth transmission line 26. The fourth resonant element 54 is configured to be coupled with the seventh other portion 27b of the seventh transmission line 27. The sixth resonant element 56 is configured to be coupled with the eighth other portion 28b of the eighth transmission line 28.

The third resonant element 53 is configured to resonate at the third frequency f3. The fourth resonant element 54 is configured to resonate at the fourth frequency f4. The fifth resonant element 55 is configured to resonate at the fifth frequency f5. The sixth resonant element 56 is configured to resonate at the sixth frequency f6.

As already explained, the intermediate portion 20c has the first intermediate portion electrical length θc1 at a first center frequency fc1 that is ½ the sum of the first frequency f1 and the second frequency f2. The intermediate portion 20c has a second intermediate portion electrical length θc2 at the second center frequency fc2 that is ½ the sum of the third frequency f3 and the fourth frequency f4. The intermediate portion 20c has a third intermediate portion electrical length θc3 at a third center frequency fc3 that is ½ the sum of the fifth frequency f5 and the sixth frequency f6.

The third transmission line 23 has the third electrical length θ3 at the second center frequency fc2. The fourth transmission line 24 has the fourth electrical length θ4 at the second center frequency fc2. The fifth transmission line 25 has a fifth electrical length θ5 at the second center frequency fc2. The seventh transmission line 27 has a seventh electrical length θ7 at the second center frequency fc2.

The third transmission line 23 has a third other electrical length θ3A at the third center frequency fc3. The fourth transmission line 24 has a fourth other electrical length θ4A at the third center frequency fc3. The sixth transmission line 26 has a sixth electrical length θ6 at the third center frequency fc3. The eighth transmission line 28 has an eighth electrical length θ8 at the third center frequency fc3.

The second sum of the second intermediate electrical length θc2, the third electrical length θ3, the fifth electrical length θ5, the fourth electrical length θ4, and the seventh electrical length θ7 is (2m+1)×90 degrees. “m” is an integer greater than or equal to 0.

The third sum of the third intermediate electrical length θc3, the third other electrical length θ3A, the sixth electrical length θ6, the fourth other electrical length θ4A, and the eighth electrical length θ8 is (2l+1)×90 degrees. “l” is an integer equal to or greater than 0.

By the second sum being an odd multiple of 90 degrees, good attenuation characteristics are obtained in the second band including the third frequency f3 and the fourth frequency f4. By the third sum being an odd multiple of 90 degrees, good attenuation characteristics are obtained in the third band including the fifth frequency f5 and the sixth frequency f6.

The third frequency f3, the fourth frequency f4, the fifth frequency f5, and the sixth frequency f6 are not less than the lower limit frequency and not more than the upper limit frequency of the target band.

The third frequency f3 may be the same as the fourth frequency f4. The third frequency f3 may be different from the fourth frequency f4. The fifth frequency f5 may be the same as the sixth frequency f6. The fifth frequency f5 may be different from the sixth frequency f6.

The third transmission line 23 has a third characteristic impedance Z3. The fourth transmission line 24 has a fourth characteristic impedance Z4. The fifth transmission line 25 has a fifth characteristic impedance Z5. The sixth transmission line 26 has a sixth characteristic impedance Z6. The seventh transmission line 27 has a seventh characteristic impedance Z7. The eighth transmission line 28 has an eighth characteristic impedance Z8. These characteristic impedances may be set arbitrarily.

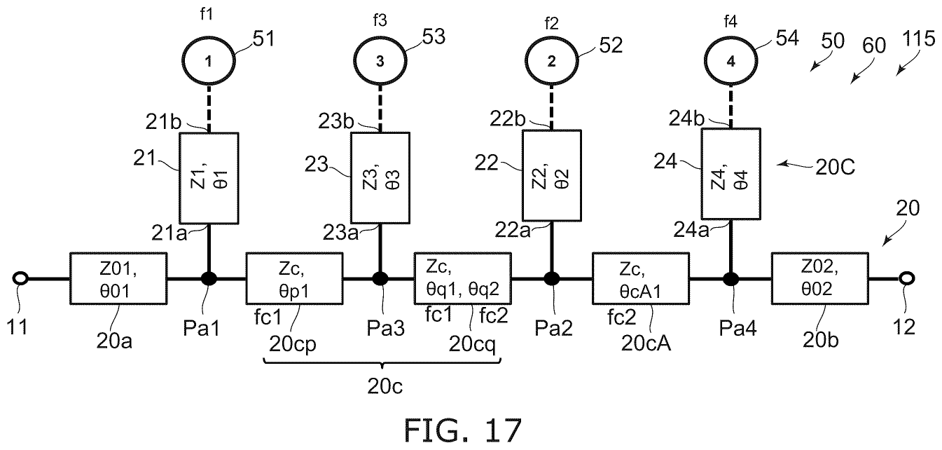

FIG. 17 is a schematic diagram illustrating a filter circuit according to the first embodiment.

As illustrated in FIG. 17, in a filter circuit 115 according to the embodiment, a third connection point Pa3 and a fourth connection point Pa4 are provided. Except for this, the configuration of the above-mentioned filter circuit (such as the filter circuit 110) can be applied to the filter circuit 115.

In the filter circuit 115, the transmission line 20 further includes another intermediate portion 20cA between the intermediate portion 20c and the output portion 20b. The intermediate portion 20c includes the first partial intermediate portion 20cp and the second partial intermediate portion 20cq.

The plurality of coupling transmission lines 20C further include the third transmission line 23 and the fourth transmission line 24. The plurality of resonant elements 50 further include the third resonant element 53 and the fourth resonant element 54.

The third portion 23a of the third transmission line 23 is configured to be coupled with the third connection point Pa3 between the first partial intermediate portion 20cp and the second partial intermediate portion 20cq. The third resonant element 53 is configured to be coupled with the third other portion 23b of the third transmission line 23. The third resonant element 53 is configured to resonate at the third frequency f3.

The fourth portion 24a of the fourth transmission line 24 is configured to be coupled with the fourth connection point Pa4 between the intermediate portion 20c and the other intermediate portion 20cA. The fourth resonant element 54 is configured to be coupled with the fourth other portion 24b of the fourth transmission line 24. The fourth resonant element 54 is configured to resonate at the fourth frequency f4.

The first partial intermediate portion 20cp has a first partial intermediate portion electrical length θp1 at the first center frequency fc1. The second partial intermediate portion 20cq has the second partial intermediate portion electrical length θq1 at the first center frequency fc1. The first intermediate portion electrical length θc1 is the sum of the first partial intermediate portion electrical length θp1 and the second partial intermediate portion electrical length θq1.

The other intermediate portion 20cA has an other intermediate portion electrical length θcA1 at the second center frequency fc2 between the third frequency f3 and the fourth frequency f4. The second partial intermediate portion 20cq has a second other partial intermediate portion electrical length θq2 at the second center frequency fc2.

The third transmission line 23 has a third electrical length θ3 at the second center frequency fc2. The fourth transmission line 24 has a fourth electrical length θ4 at the second center frequency fc2.

In the filter circuit 114, the fourth sum of the third electrical length θ3, the second other partial intermediate portion electrical length θq2, the other intermediate portion electrical length θcA1, and the fourth electrical length θ4 is (2q+1)×90 degrees. “q” is an integer greater than or equal to 0.

In the filter circuit 114, good attenuation characteristics are obtained in the first band including the first frequency f1 and the second frequency f2, and in the second band including the third frequency f3 and the fourth frequency f4.

In the filter circuit 114, the third frequency f3 may be the same as the fourth frequency f4. The third frequency f3 may be different from the fourth frequency f4.

In the filter circuit 115, the first partial intermediate portion electrical length θp1 may be an integer multiple of 180 degrees. The other intermediate portion electrical length θcA1 may be an integer multiple of 180 degrees. For example, each of the first partial intermediate portion electrical length θp1 and the other intermediate portion electrical length θcA1 may be substantially 0 degrees. For example, a first band of attenuation and a second band of attenuation are obtained separately.

In the embodiment, a plurality of transmission lines may be coupled with one connection point. For example, a plurality of first transmission lines 21 and a plurality of third transmission lines 23 may be coupled to the first connection point Pa1. The first resonant element 51 may be coupled with each of the first transmission lines 21. The third resonant element 53 may be coupled with each of the third transmission lines 23. A plurality of second transmission lines 22 and a plurality of fourth transmission lines 24 may be coupled to the second connection point Pa2. The second resonant element 52 may be coupled with each of the second transmission lines 22. The fourth resonant element 54 may be coupled with each of the fourth transmission lines 24.

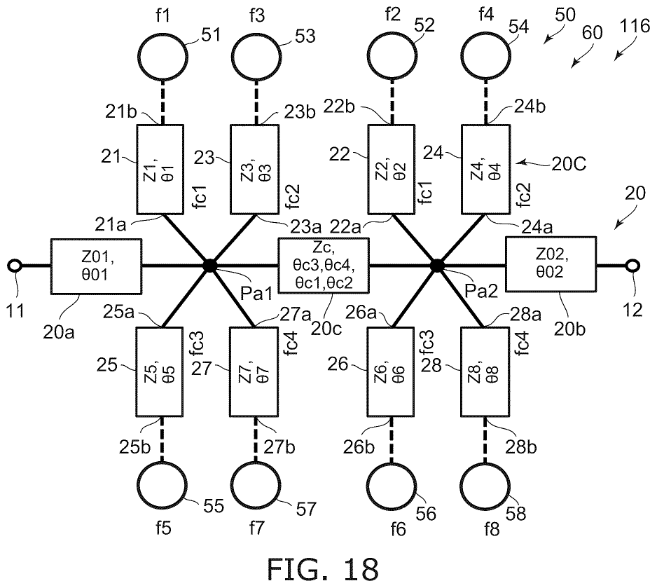

FIG. 18 is a schematic diagram illustrating a filter circuit according to the first embodiment.

As illustrated in FIG. 18, in a filter circuit 116 according to the embodiment, the plurality of coupling transmission lines 20C further includes a fifth transmission line 25 and a sixth transmission line 26. The plurality of resonant elements 50 further include a fifth resonant element 55 and a sixth resonant element 56. The configuration of the filter circuit 116 except for these elements may be the same as the configuration of the filter circuit 110.

In the filter circuit 116, the fifth portion 25a of the fifth transmission line 25 is configured to be coupled with the first connection point Pa1. The sixth portion 26a of the sixth transmission line 26 is configured to be coupled with the second connection point Pa2. The fifth resonant element 55 is configured to be coupled with the fifth other portion 25b of the fifth transmission line 25. The sixth resonant element 56 is configured to be coupled with the sixth other portion 26b of the sixth transmission line 26.

The fifth resonant element 55 is configured to resonate at a fifth frequency f5. The sixth resonant element 56 is configured to resonate at a sixth frequency f6. The fifth frequency f5 and the sixth frequency f6 are not less than the lower limit frequency and not more than the upper limit frequency of the target band.

The intermediate portion 20c has a third intermediate portion electrical length θc3 at the third center frequency fc3 that is ½ the sum of the fifth frequency f5 and the sixth frequency f6. The fifth transmission line 25 has a fifth electrical length θ5 at the third center frequency fc3. The sixth transmission line 26 has a sixth electrical length θ6 at the third center frequency fc3.

In the embodiment, the third sum of the third intermediate portion electrical length θc3, the fifth electrical length θ5, and the sixth electrical length θ6 is (2l+1)×90 degrees. “l” is an integer greater than or equal to 0.

In the band including the fifth frequency f5 and the sixth frequency f6, good attenuation characteristics are effectively obtained. For example, there is a high degree of freedom in the positions of the fifth resonant element 55 and the sixth resonant element 56. The overall size of the circuit can be reduced. The electrical length of the intermediate portion 20c can be shortened. For example, the transmission loss can be reduced with a small size. A filter circuit with improved characteristics can be provided.

For example, a filter circuit including a first band including the first frequency f1 and the second frequency f2, and a third band including the fifth frequency f5 and the sixth frequency f6 can be obtained. Signals are attenuated in the first band and the third band. The filter circuit 116 attenuates the components of the first band and the third band.

The fifth frequency f5 may be the same as the sixth frequency f6. The fifth frequency f5 may be different from the sixth frequency f6.

The fifth transmission line 25 has a fifth characteristic impedance Z5. The sixth transmission line 26 has a sixth characteristic impedance Z6. These characteristic impedances may be set arbitrarily.

In the filter circuit 116, the plurality of coupling transmission lines 20C may further include a seventh transmission line 27 and an eighth transmission line 28. The plurality of resonant elements 50 may further include a seventh resonant element 57 and an eighth resonant element 58.

The seventh portion 27a of the seventh transmission line 27 is configured to be coupled with the first connection point Pa1. The eighth portion 28a of the eighth transmission line 28 is configured to be coupled with the second connection point Pa2. The seventh resonant element 57 is configured to be coupled with the seventh other portion 27b of the seventh transmission line 27. The eighth resonant element 58 is configured to be coupled with the eighth other portion 28b of the eighth transmission line 28.

The seventh resonant element 57 is configured to resonate at a seventh frequency f7. The eighth resonant element 58 is configured to resonate at an eighth frequency f8. The seventh frequency f7 and the eighth frequency f8 are not less than the lower limit frequency and not more than the upper limit frequency of the target band.

The intermediate portion 20c has a fourth intermediate portion electrical length θc4 at a fourth center frequency fc4 that is ½ the sum of the seventh frequency f7 and the eighth frequency f8. The seventh transmission line 27 has a seventh electrical length θ7 at the fourth center frequency fc4. The eighth transmission line 28 has an eighth electrical length θ8 at the fourth center frequency fc4.

In the embodiment, the fourth sum of the fourth intermediate portion electrical length θc4, the seventh electrical length θ7, and the eighth electrical length θ8 is (2q+1)×90 degrees. “q” is an integer equal to or greater than 0.

In a band including the seventh frequency f7 and the eighth frequency f8, good attenuation characteristics are effectively obtained. For example, there is a high degree of freedom in the positions of the seventh resonant element 57 and the eighth resonant element 58. The overall size of the circuit can be reduced. The electrical length of the intermediate portion 20c can be shortened. For example, the transmission loss can be reduced with a small size. A filter circuit with improved characteristics can be provided.

For example, a filter circuit is obtained that includes a third band including the third frequency f3 and the fourth frequency f4, and a fourth band including the seventh frequency f7 and the eighth frequency f8. Signals are attenuated in the first and third bands. The filter circuit 116 attenuates the components of the second band and the fourth band.

The seventh frequency f7 may be the same as the eighth frequency f8. The seventh frequency f7 may be different from the eighth frequency f8.

The seventh transmission line 27 has a seventh characteristic impedance Z7. The eighth transmission line 28 has an eighth characteristic impedance Z8. These characteristic impedances may be set arbitrarily.

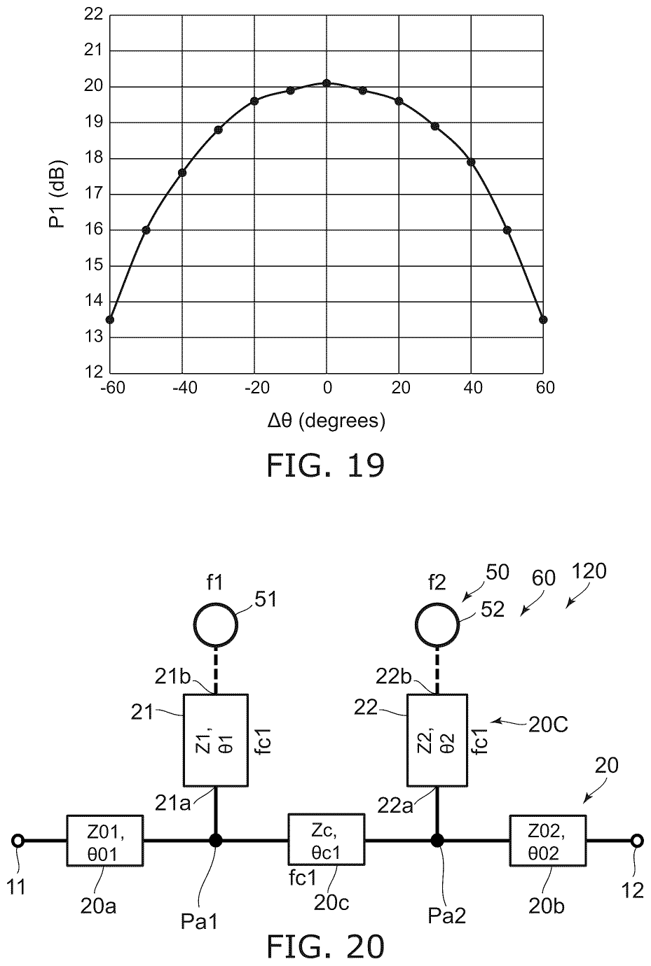

FIG. 19 is a graph illustrating the characteristics of the filter according to the first embodiment.

FIG. 19 illustrates a simulation result of the characteristics when the first sum (the sum of the first intermediate portion electrical length θc1, the first electrical length θ1, and the second electrical length θ2) is changed in the filter circuit 110 illustrated in FIG. 1. In FIG. 19, the horizontal axis is the electrical length difference Δθ. The electrical length difference Δθ corresponds to the difference between the first sum and 90 degrees. The vertical axis is an attenuation P1. As shown in FIG. 19, when the absolute value of the electrical length difference Δθ increases, the attenuation P1 decreases. The absolute value of the electrical length difference Δθ may be 20 degrees or less. A good attenuation P1 can be obtained. The absolute value of the electrical length difference Δθ may be 10 degrees or less. The absolute value of the electrical length difference Δθ may be 10 degrees or less. Better characteristics can be obtained.

The characteristics illustrated in FIG. 19 can also be applied in a case where the electrical length difference Δθ is the difference between the first sum and (2n+1)×90 degrees. In the embodiment, the first absolute value of the difference between the first sum and (2n+1)×90 degrees may be 20 degrees or less. The first absolute value is preferably 10 degrees or less. It is more preferable that the first absolute value is 5 degrees or less.

For example, in the embodiment, the second absolute value of the difference between the second sum and (2m+1)×90 degrees may be 20 degrees or less. The second absolute value is preferably 10 degrees or less. It is more preferable that the second absolute value is 5 degrees or less. The third absolute value of the difference between the third sum and (2l+1)×90 degrees may be 20 degrees or less. The third absolute value is preferably 10 degrees or less. It is more preferable that the third absolute value is 5 degrees or less.

FIG. 20 is a schematic diagram illustrating a filter circuit according to the first embodiment.

In a filter circuit 120 according to the embodiment illustrated in FIG. 20, the first sum is an integer multiple of 180 degrees. Except for this, the configuration of the above-mentioned filter circuits (such as filter circuit 110) can be applied to the filter circuit 116.

Thus, the filter circuit 120 includes the first terminal 11, the second terminal 12, and the filter element 60. The filter element 60 includes the transmission line 20, the plurality of coupling transmission lines 20C including the first transmission line 21 and the second transmission line 22, and the plurality of resonant elements 50 including the first resonant element 51 and the second resonant element 52.

The transmission line 20 includes the input portion 20a configured to be coupled to the first terminal 11, the output portion 20b configured to be coupled to the second terminal 12, and the intermediate portion 20c between the input portion 20a and the output portion 20b. The first portion 21a of the first transmission line 21 is configured to be coupled with the first connection point Pa1 between the input portion 20a and the intermediate portion 20c. The second portion 22a of the second transmission line 22 is configured to be coupled with the second connection point Pa2 between the intermediate portion 20c and the output portion 20b.

The first resonant element 51 is configured to be coupled with the first other portion 21b of the first transmission line 21. The second resonant element 52 is configured to be coupled with the second other portion 22b of the second transmission line 22. The first resonant element 51 is configured to resonate at the first frequency f1. The second resonant element 52 is configured to resonate at the second frequency f2.

The intermediate portion 20c has the first intermediate portion electrical length θc1 at the first center frequency fc1 that is ½ the sum of the first frequency f1 and the second frequency f2. The first transmission line 21 has the first electrical length θ1 at the first center frequency fc1. The second transmission line 22 has the second electrical length θ2 at the first center frequency fc1. In the filter circuit 120, the first sum of the first intermediate portion electrical length θc1, the first electrical length θ1, and the second electrical length θ2 is substantially n×180 degrees. “n” is an integer equal to or greater than 1.

In the filter circuit 120, the component of the first frequency f1 and the component of the second frequency f2 are attenuated. In the filter circuit 120, the path between the two resonant elements 50 is separated into three parts (the first transmission line 21, the intermediate portion 20c, and the second transmission line 22). For example, there is a high degree of freedom in the position of each of the plurality of resonant elements 50. For example, it is easy to design the first transmission line 21 and the second transmission line 22 so that the overall size of the circuit is small. For example, the electrical length of the intermediate portion 20c can be shortened. Losses in the intermediate portion 20c can be suppressed. The desired filter characteristics can be obtained with a small size. For example, pass loss can be reduced with a small size. According to the embodiment, a filter circuit with improved characteristics can be provided.

In the filter circuit 120, the first frequency f1 is different from the second frequency f2.

### Second Embodiment

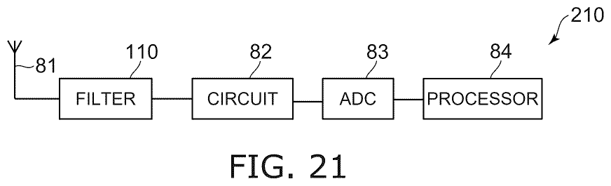

FIG. 21 is a schematic diagram illustrating a communication device according to a second embodiment.

As shown in FIG. 21, a communication device 210 according to the embodiment includes a filter circuit (such as the filter circuit 110) according to the first embodiment. In this example, the communication device 210 includes an antenna 81, a receiving/transmitting circuit 82, a converter 83, and a processor 84.

In a case where the communication device 210 is a receiving device, the communication signal received by the antenna 81 is supplied to the filter circuit 110. In the filter circuit 110, signals of the target frequency band are attenuated, and signals of other pass bands are passed. The passed signal may be subjected to processing such as detection and amplification by the receiving/transmitting circuit 82. The output of the receiving/transmitting circuit 82 is, for example, AD converted in the converter 83. The converted signal is processed in the processor 84, and the target signal (or information) is obtained.

In a case where the communication device 210 is a transmitting device, the communication signal from the receiving/transmitting circuit 82 is supplied to the antenna 81 via the filter circuit 110. In the filter circuit 110, signals of the target frequency band are attenuated, and signals of other pass bands are passed.

Thus, the communication device 210 according to the embodiment may include the filter circuit (e.g., filter circuit 110, etc.) according to the first embodiment and the receiving/transmitting circuit 82. The receiving/transmitting circuit 82 is configured to receive or transmit a communication signal via the filter circuit (e.g., filter circuit 110, etc.). The filter circuit (e.g., filter circuit 110, etc.) is configured to attenuate frequency components of a target band of the communication signal.

The filter circuit according to the embodiment may include various circuit structures. The filter circuit according to the embodiment may include circuit structures such as, for example, a coplanar structure, a strip line, a coaxial, or a waveguide.

For example, a filter circuit is used in a high-frequency device such as a transmitter or receiver. For example, there is a method in which a transmission line with an electrical length of 90 degrees is provided between plurality of reflective resonators. This can increase the attenuation in the stopband of the band-stop filter. On the other hand, when plurality of band-stop filters are synthesized, there is a method in which the plurality of band-stop filters are connected via a transmission line with an electrical length of 180 degrees. This can reduce interference. When plurality of resonators or filters are connected via a transmission line, the substrate size becomes large and the pass loss increases. According to the embodiment, the pass loss can be reduced with a small size.

In this specification, the “electrical length” may include not only the strict length but also, for example, variations in the manufacturing process. The “electrical length” may substantially be the value shown as an example.

The embodiment may include the following Technical proposals:

### Technical Proposal 1

A filter circuit, comprising:
a first terminal;
a second terminal; and
a filter element,
the filter element includes:
   a transmission line;
   a plurality of coupling transmission lines including a first transmission line and a second transmission line; and
   a plurality of resonant elements including a first resonant element and a second resonant element,
the transmission line including:
   an input portion configured to be coupled to the first terminal;
   an output portion configured to be coupled to the second terminal; and
   an intermediate portion between the input portion and the output portion,
a first portion of the first transmission line being configured to be coupled with a first connection point between the input portion and the intermediate portion,
a second portion of the second transmission line being configured to be coupled with a second connection point between the intermediate portion and the output portion,
the first resonant element being configured to be coupled with a first other portion of the first transmission line,
the second resonant element being configured to be coupled with a second other portion of the second transmission line,
the first resonant element being configured to resonate at a first frequency,
the second resonant element being configured to resonate at a second frequency,
the intermediate portion having a first intermediate portion electrical length θc1 at a first center frequency being ½ a sum of the first frequency and the second frequency,
the first transmission line having a first electrical length θ1 at the first center frequency,
the second transmission line having a second electrical length θ2 at the first center frequency,
a first sum of the first intermediate portion electrical length θc1, the first electrical length θ1, and the second electrical length θ2 being substantially (2n+1)×90 degrees, and
n is an integer equal to or greater than 0.

### Technical Proposal 2

The filter circuit according to Technical proposal 1, wherein
an absolute value of a difference between the first sum and (2n+1)×90 degrees is 20 degrees or less.

### Technical Proposal 3

The filter circuit according to Technical proposal 1, wherein
the first transmission line includes a plurality of first partial transmission lines configured to be coupled with each other,
the second transmission line includes a plurality of second partial transmission lines configured to be coupled with each other,
the first electrical length θ1 is a total electrical length of the plurality of first partial transmission lines at the first center frequency, and
the second electrical length θ2 is a total electrical length of the plurality of second partial transmission lines at the first center frequency.

### Technical Proposal 4

The filter circuit according to Technical proposal 1, wherein
the intermediate portion includes a plurality of partial intermediate portions configured to be coupled with each other, and
the first intermediate portion electrical length θc1 is a total electrical length of the plurality of partial intermediate portions at the first center frequency.

### Technical Proposal 5

The filter circuit according to Technical proposal 4, wherein
a first line width of one of the plurality of intermediate portions is different from a second line width of another one of the plurality of intermediate portions.

### Technical Proposal 6

The filter circuit according to Technical proposal 1, wherein
the plurality of coupling transmission lines further include a third transmission line and a fourth transmission line,
the plurality of resonant elements further include a third resonant element and a fourth resonant element,
the third portion of the third transmission line is configured to be coupled with the first connection point,
the fourth portion of the fourth transmission line is configured to be coupled with the second connection point,
the third resonant element is configured to be coupled with a third other portion of the third transmission line,
the fourth resonant element is configured to be coupled with a fourth other portion of the fourth transmission line,
the third resonant element is configured to resonate at a third frequency,
the fourth resonant element is configured to resonate at a fourth frequency,
the intermediate portion has a second intermediate portion electrical length θc2 at a second center frequency being ½ a sum of the third frequency and the fourth frequency,
the third transmission line has a third electrical length θ3 at the second center frequency,
the fourth transmission line has a fourth electrical length θ4 at the second center frequency,
a second sum of the second intermediate portion electrical length θc2, the third electrical length θ3, and the fourth electrical length θ4 is (2m+1)×90 degrees, and
m is an integer greater than or equal to 0.

### Technical Proposal 7

The filter circuit according to Technical proposal 6, wherein
the third transmission line includes a plurality of third partial transmission lines configured to be coupled with each other,
the fourth transmission line includes a plurality of fourth partial transmission lines configured to be coupled with each other,
the third electrical length θ3 is a total electrical length of the plurality of third partial transmission lines at the second center frequency, and
the fourth electrical length θ4 is a total electrical length of the plurality of fourth partial transmission lines at the second center frequency.

### Technical Proposal 8

The filter circuit according to Technical proposal 1, wherein
the plurality of coupling transmission lines further includes a third transmission line, a fourth transmission line, a fifth transmission line, a sixth transmission line, a seventh transmission line, and an eighth transmission line,
the plurality of resonant elements further includes a third resonant element, a fourth resonant element, a fifth resonant element, and a sixth resonant element,
a third portion of the third transmission line is configured to be coupled with the first connection point,
a fifth portion of the fifth transmission line is configured to be coupled with a third other portion of the third transmission line,
a sixth portion of the sixth transmission line is configured to be coupled with the third other portion,
a fourth portion of the fourth transmission line is configured to be coupled with the second connection point,
a seventh portion of the seventh transmission line is configured to be coupled with a fourth other portion of the fourth transmission line,
an eighth portion of the eighth transmission line is configured to be coupled with the fourth other portion,
the third resonant element is configured to be coupled with a fifth other portion of the fifth transmission line,
the fifth resonant element is configured to be coupled with a sixth other portion of the sixth transmission line,
the fourth resonant element is configured to be coupled with a seventh other portion of the seventh transmission line,
the sixth resonant element is configured to be coupled with an eighth other portion of the eighth transmission line,
the third resonant element is configured to resonate at a third frequency,
the fourth resonant element is configured to resonate at a fourth frequency,
the fifth resonant element is configured to resonate at a fifth frequency,
the sixth resonant element is configured to resonate at a sixth frequency,
the intermediate portion has a second intermediate portion electrical length θc2 at a second center frequency being ½ a sum of the third frequency and the fourth frequency,
the intermediate portion has a third intermediate portion electrical length θc3 at a third center frequency being ½ a sum of the fifth frequency and the sixth frequency,
the third transmission line has a third electrical length θ3 at the second center frequency,
the fourth transmission line has a fourth electrical length θ4 at the second center frequency,
the fifth transmission line has a fifth electrical length θ5 at the second center frequency,
the seventh transmission line has a seventh electrical length θ7 at the second center frequency,
the third transmission line has a third other electrical length θ3A at the third center frequency,
the fourth transmission line has a fourth other electrical length θ4A at the third center frequency,
the sixth transmission line has a sixth electrical length θ6 at the third center frequency,
the eighth transmission line has an eighth electrical length θ8 at the third center frequency,
a second sum of the second intermediate portion electrical length θc2, the third electrical length θ3, the fifth electrical length θ5, the fourth electrical length θ4, and the seventh electrical length θ7 is (2m+1)×90 degrees,
m is an integer equal to or greater than 0,
a third sum of the third intermediate portion electrical length θc3, the third other electrical length θ3A, the sixth electrical length θ6, the fourth other electrical length θ4A, and the eighth electrical length θ8 is (2l+1)×90 degrees, and
l is an integer equal to or greater than 0.

### Technical Proposal 9

The filter circuit according to Technical proposal 1, wherein
the transmission line further includes another intermediate portion between the intermediate portion and the output portion,
the intermediate portion includes a first partial intermediate portion and a second partial intermediate portion,
the plurality of coupling transmission lines further include a third transmission line and a fourth transmission line,
the plurality of resonant elements further include a third resonant element and a fourth resonant element,
the third portion of the third transmission line is configured to be coupled with a third connection portion between the first partial intermediate portion and the second partial intermediate portion,
the third resonant element is configured to be coupled with a third other portion of the third transmission line,
the third resonant element is configured to resonate at a third frequency,
the fourth portion of the fourth transmission line is configured to be coupled with a fourth connection point between the intermediate portion and the other intermediate portion,
the fourth resonant element is configured to be coupled with a fourth other portion of the fourth transmission line,
the fourth resonant element is configured to resonate at a fourth frequency,
the first partial intermediate portion has a first partial intermediate portion electrical length θp1 at the first center frequency,
the second partial intermediate portion has a second partial intermediate portion electrical length θq1 at the first center frequency,
the first intermediate portion electrical length θc1 is a sum of the first partial intermediate portion electrical length θp1 and the second partial intermediate portion electrical length θq1,
the other intermediate portion has an other intermediate portion electrical length θcA1 at a second center frequency between the third frequency and the fourth frequency,
the second partial intermediate portion has a second other partial intermediate portion electrical length θq2 at the second center frequency,
the third transmission line has a third electrical length θ3 at the second center frequency,
the fourth transmission line has a fourth electrical length θ4 at the second center frequency,
a fourth sum of the third electrical length θ3, the second other partial intermediate portion electrical length θq2, the other intermediate portion electrical length θcA1, and the fourth electrical length θ4 is (2q+1)×90 degrees, and
q is an integer equal to or greater than 0.

### Technical Proposal 10

The filter circuit according to any one of Technical proposals 1 to 9, wherein
the first frequency is the same as the second frequency, and
the second electrical length θ2 is different from the first electrical length θ1.

### Technical Proposal 11

The filter circuit according to any one of Technical proposals 1 to 9, wherein
the first frequency is different from the second frequency, and
the second electrical length θ2 is the same as the first electrical length θ1.

### Technical Proposal 12

The filter circuit according to any one of Technical proposals 1 to 11, wherein
at least one of the first resonant element or the second resonant element includes a first conductive portion, a second conductive portion, and a third conductive portion between the first conductive portion and the second conductive portion, and
a third conductive portion line width of the third conductive portion is narrower than a first conductive portion line width of the first conductive portion and narrower than a second conductive portion line width of the second conductive portion.

### Technical Proposal 13

The filter circuit according to any one of Technical proposals 1 to 11, wherein
an end of at least one of the first resonant element or the second resonant element is open, and
another end of the at least one of the first resonant element or the second resonant element is grounded.

### Technical Proposal 14

The filter circuit according to any one of Technical proposals 1 to 11, wherein
at least one of the first resonant element or the second resonant element includes a variable frequency resonator,
one end of the variable frequency resonator is grounded, and
a variable capacitance element is connected to another end of the variable frequency resonator.

### Technical Proposal 15

The filter circuit according to any one of Technical proposals 1 to 11, wherein
at least one of the first resonant element and the second resonant element includes an LC resonator,
the LC resonator includes a lumped constant element, and
the lumped constant element includes an inductive element and a capacitive element.

### Technical Proposal 16

The filter circuit according to Technical proposal 1, comprising a plurality of the filter elements,
two of the plurality of the filter elements are configured to be coupled with each other.

### Technical Proposal 17

The filter circuit according to Technical proposal 15, wherein
a first frequency of the first resonant element included in one of the plurality of filter elements is different from the first frequency of the first resonant element included in another one of the plurality of filter elements, and
a second frequency of the second resonant element included in the one of the plurality of filter elements is different from the second frequency of the second resonant element included in the other one of the plurality of filter elements.

### Technical Proposal 18

A filter circuit, comprising:
a first terminal;
a second terminal; and
a filter element,
the filter element including:
   a transmission line;
   a plurality of coupling transmission lines including a first transmission line and a second transmission line; and
   a plurality of resonant elements including a first resonant element and a second resonant element,
the transmission line including:
   an input portion configured to be coupled to the first terminal;
   an output portion configured to be coupled to the second terminal; and
   an intermediate portion between the input portion and the output portion,
a first portion of the first transmission line configured to be coupled with a first connection point between the input portion and the intermediate portion,
a second portion of the second transmission line configured to be coupled with a second connection point between the intermediate portion and the output portion,
the first resonant element configured to be coupled with a first other portion of the first transmission line,
the second resonant element configured to be coupled with a second other portion of the second transmission line,
the first resonant element configured to resonate at a first frequency,
the second resonant element configured to resonate at a second frequency,
the intermediate portion having a first intermediate portion electrical length θc1 at a first center frequency being ½ a sum of the first frequency and the second frequency,
the first transmission line having a first electrical length θ1 at the first center frequency,
the second transmission line having a second electrical length θ2 at the first center frequency,
a first sum of the first intermediate portion electrical length θc1, the first electrical length θ1, and the second electrical length θ2 being substantially n×180 degrees, and
n is an integer greater than or equal to 1.

### Technical Proposal 19

The filter circuit according to Technical proposal 18, wherein
the first frequency is different from the second frequency.

### Technical Proposal 20

A communication device comprising:
a filter circuit according to any one of Technical proposals 1 to 19; and
a receiving/transmitting circuit configured to receive or transmit a communication signal via the filter circuit,
the filter circuit being configured to attenuate frequency components of a target band including the first frequency and the second frequency and being included in the communication signal.

According to the embodiment, a filter circuit and a communication device are provided that can improve the characteristics.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the filter circuits such as terminals, transmission lines, resonant elements, conductive layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all filter circuits and all communication devices practicable by an appropriate design modification by one skilled in the art based on the filter circuits and the communication devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A filter circuit, comprising:
a first terminal;
a second terminal; and
a filter element,
the filter element includes:
a transmission line;
a plurality of coupling transmission lines including a first transmission line and a second transmission line; and
a plurality of resonant elements including a first resonant element and a second resonant element,
the transmission line including:
an input portion configured to be coupled to the first terminal;
an output portion configured to be coupled to the second terminal; and
an intermediate portion between the input portion and the output portion,
a first portion of the first transmission line being configured to be coupled with a first connection point between the input portion and the intermediate portion,
a second portion of the second transmission line being configured to be coupled with a second connection point between the intermediate portion and the output portion,
the first resonant element being configured to be coupled with a first other portion of the first transmission line,
the second resonant element being configured to be coupled with a second other portion of the second transmission line,
the first resonant element being configured to resonate at a first frequency,
the second resonant element being configured to resonate at a second frequency,
the intermediate portion having a first intermediate portion electrical length θc1 at a first center frequency being ½ a sum of the first frequency and the second frequency,
the first transmission line having a first electrical length θ1 at the first center frequency,
the second transmission line having a second electrical length θ2 at the first center frequency,
a first sum of the first intermediate portion electrical length θc1, the first electrical length θ1, and the second electrical length θ2 being substantially (2n+1)×90 degrees, and
n is an integer equal to or greater than 0.

2. The filter circuit according to claim 1, wherein
an absolute value of a difference between the first sum and (2n+1)×90 degrees is 20 degrees or less.

3. The filter circuit according to claim 1, wherein
the first transmission line includes a plurality of first partial transmission lines configured to be coupled with each other,
the second transmission line includes a plurality of second partial transmission lines configured to be coupled with each other,
the first electrical length θ1 is a total electrical length of the plurality of first partial transmission lines at the first center frequency, and
the second electrical length θ2 is a total electrical length of the plurality of second partial transmission lines at the first center frequency.

4. The filter circuit according to claim 1, wherein
the intermediate portion includes a plurality of partial intermediate portions configured to be coupled with each other, and
the first intermediate portion electrical length θc1 is a total electrical length of the plurality of partial intermediate portions at the first center frequency.

5. The filter circuit according to claim 4, wherein
a first line width of one of the plurality of intermediate portions is different from a second line width of another one of the plurality of intermediate portions.

6. The filter circuit according to claim 1, wherein
the plurality of coupling transmission lines further include a third transmission line and a fourth transmission line,
the plurality of resonant elements further include a third resonant element and a fourth resonant element,
the third portion of the third transmission line is configured to be coupled with the first connection point,
the fourth portion of the fourth transmission line is configured to be coupled with the second connection point,
the third resonant element is configured to be coupled with a third other portion of the third transmission line,
the fourth resonant element is configured to be coupled with a fourth other portion of the fourth transmission line,
the third resonant element is configured to resonate at a third frequency,
the fourth resonant element is configured to resonate at a fourth frequency,
the intermediate portion has a second intermediate portion electrical length θc2 at a second center frequency being ½ a sum of the third frequency and the fourth frequency,
the third transmission line has a third electrical length θ3 at the second center frequency,
the fourth transmission line has a fourth electrical length θ4 at the second center frequency,
a second sum of the second intermediate portion electrical length θc2, the third electrical length θ3, and the fourth electrical length θ4 is (2m+1)×90 degrees, and
m is an integer greater than or equal to 0.

7. The filter circuit according to claim 6, wherein
the third transmission line includes a plurality of third partial transmission lines configured to be coupled with each other,
the fourth transmission line includes a plurality of fourth partial transmission lines configured to be coupled with each other,
the third electrical length θ3 is a total electrical length of the plurality of third partial transmission lines at the second center frequency, and
the fourth electrical length θ4 is a total electrical length of the plurality of fourth partial transmission lines at the second center frequency.

8. The filter circuit according to claim 1, wherein
the plurality of coupling transmission lines further includes a third transmission line, a fourth transmission line, a fifth transmission line, a sixth transmission line, a seventh transmission line, and an eighth transmission line,
the plurality of resonant elements further includes a third resonant element, a fourth resonant element, a fifth resonant element, and a sixth resonant element,
a third portion of the third transmission line is configured to be coupled with the first connection point,
a fifth portion of the fifth transmission line is configured to be coupled with a third other portion of the third transmission line,
a sixth portion of the sixth transmission line is configured to be coupled with the third other portion,
a fourth portion of the fourth transmission line is configured to be coupled with the second connection point,
a seventh portion of the seventh transmission line is configured to be coupled with a fourth other portion of the fourth transmission line,
an eighth portion of the eighth transmission line is configured to be coupled with the fourth other portion,
the third resonant element is configured to be coupled with a fifth other portion of the fifth transmission line,
the fifth resonant element is configured to be coupled with a sixth other portion of the sixth transmission line,
the fourth resonant element is configured to be coupled with a seventh other portion of the seventh transmission line,
the sixth resonant element is configured to be coupled with an eighth other portion of the eighth transmission line,
the third resonant element is configured to resonate at a third frequency,
the fourth resonant element is configured to resonate at a fourth frequency,
the fifth resonant element is configured to resonate at a fifth frequency,
the sixth resonant element is configured to resonate at a sixth frequency,
the intermediate portion has a second intermediate portion electrical length θc2 at a second center frequency being ½ a sum of the third frequency and the fourth frequency,
the intermediate portion has a third intermediate portion electrical length θc3 at a third center frequency being ½ a sum of the fifth frequency and the sixth frequency,
the third transmission line has a third electrical length θ3 at the second center frequency,
the fourth transmission line has a fourth electrical length θ4 at the second center frequency,
the fifth transmission line has a fifth electrical length θ5 at the second center frequency,
the seventh transmission line has a seventh electrical length θ7 at the second center frequency,
the third transmission line has a third other electrical length θ3A at the third center frequency,
the fourth transmission line has a fourth other electrical length θ4A at the third center frequency,
the sixth transmission line has a sixth electrical length θ6 at the third center frequency,
the eighth transmission line has an eighth electrical length θ8 at the third center frequency,
a second sum of the second intermediate portion electrical length θc2, the third electrical length θ3, the fifth electrical length θ5, the fourth electrical length θ4, and the seventh electrical length θ7 is (2m+1)×90 degrees,
m is an integer equal to or greater than 0,
a third sum of the third intermediate portion electrical length θc3, the third other electrical length θ3A, the sixth electrical length θ6, the fourth other electrical length θ4A, and the eighth electrical length θ8 is (2l+1)×90 degrees, and
l is an integer equal to or greater than 0.

9. The filter circuit according to claim 1, wherein
the transmission line further includes another intermediate portion between the intermediate portion and the output portion,
the intermediate portion includes a first partial intermediate portion and a second partial intermediate portion,
the plurality of coupling transmission lines further include a third transmission line and a fourth transmission line,
the plurality of resonant elements further include a third resonant element and a fourth resonant element,
the third portion of the third transmission line is configured to be coupled with a third connection portion between the first partial intermediate portion and the second partial intermediate portion,
the third resonant element is configured to be coupled with a third other portion of the third transmission line,
the third resonant element is configured to resonate at a third frequency,
the fourth portion of the fourth transmission line is configured to be coupled with a fourth connection point between the intermediate portion and the other intermediate portion,
the fourth resonant element is configured to be coupled with a fourth other portion of the fourth transmission line,
the fourth resonant element is configured to resonate at a fourth frequency,
the first partial intermediate portion has a first partial intermediate portion electrical length θp1 at the first center frequency,
the second partial intermediate portion has a second partial intermediate portion electrical length θq1 at the first center frequency,
the first intermediate portion electrical length θc1 is a sum of the first partial intermediate portion electrical length θp1 and the second partial intermediate portion electrical length θq1,
the other intermediate portion has an other intermediate portion electrical length θcA1 at a second center frequency between the third frequency and the fourth frequency,
the second partial intermediate portion has a second other partial intermediate portion electrical length θq2 at the second center frequency,
the third transmission line has a third electrical length θ3 at the second center frequency,
the fourth transmission line has a fourth electrical length θ4 at the second center frequency,
a fourth sum of the third electrical length θ3, the second other partial intermediate portion electrical length θq2, the other intermediate portion electrical length θcA1, and the fourth electrical length θ4 is (2q+1)×90 degrees, and
q is an integer equal to or greater than 0.

10. The filter circuit according to claim 1, wherein
the first frequency is the same as the second frequency, and
the second electrical length θ2 is different from the first electrical length θ1.

11. The filter circuit according to claim 1, wherein
the first frequency is different from the second frequency, and
the second electrical length θ2 is the same as the first electrical length θ1.

12. The filter circuit according to claim 1, wherein
at least one of the first resonant element or the second resonant element includes a first conductive portion, a second conductive portion, and a third conductive portion between the first conductive portion and the second conductive portion, and
a third conductive portion line width of the third conductive portion is narrower than a first conductive portion line width of the first conductive portion and narrower than a second conductive portion line width of the second conductive portion.

13. The filter circuit according to claim 1, wherein
an end of at least one of the first resonant element or the second resonant element is open, and
another end of the at least one of the first resonant element or the second resonant element is grounded.

14. The filter circuit according to claim 1, wherein
at least one of the first resonant element or the second resonant element includes a variable frequency resonator,
one end of the variable frequency resonator is grounded, and
a variable capacitance element is connected to another end of the variable frequency resonator.

15. The filter circuit according to claim 1, wherein
at least one of the first resonant element and the second resonant element includes an LC resonator,
the LC resonator includes a lumped constant element, and
the lumped constant element includes an inductive element and a capacitive element.

16. The filter circuit according to claim 1, further comprising:
a plurality of the filter elements, wherein
two of the plurality of the filter elements are configured to be coupled with each other.

17. The filter circuit according to claim 15, wherein
a first frequency of the first resonant element included in one of the plurality of filter elements is different from the first frequency of the first resonant element included in another one of the plurality of filter elements, and
a second frequency of the second resonant element included in the one of the plurality of filter elements is different from the second frequency of the second resonant element included in the other one of the plurality of filter elements.

18. A filter circuit, comprising:
a first terminal;
a second terminal; and
a filter element,
the filter element including:
a transmission line;
a plurality of coupling transmission lines including a first transmission line and a second transmission line; and
a plurality of resonant elements including a first resonant element and a second resonant element,
the transmission line including:
an input portion configured to be coupled to the first terminal;
an output portion configured to be coupled to the second terminal; and
an intermediate portion between the input portion and the output portion,
a first portion of the first transmission line configured to be coupled with a first connection point between the input portion and the intermediate portion,
a second portion of the second transmission line configured to be coupled with a second connection point between the intermediate portion and the output portion,
the first resonant element configured to be coupled with a first other portion of the first transmission line,
the second resonant element configured to be coupled with a second other portion of the second transmission line,
the first resonant element configured to resonate at a first frequency,
the second resonant element configured to resonate at a second frequency,
the intermediate portion having a first intermediate portion electrical length θc1 at a first center frequency being ½ a sum of the first frequency and the second frequency,
the first transmission line having a first electrical length θ1 at the first center frequency,
the second transmission line having a second electrical length θ2 at the first center frequency,
a first sum of the first intermediate portion electrical length θc1, the first electrical length θ1, and the second electrical length θ2 being substantially n×180 degrees, and
n is an integer greater than or equal to 1.

19. The filter circuit according to claim 18, wherein
the first frequency is different from the second frequency.

20. A communication device comprising:
a filter circuit according to claim 1; and
a receiving/transmitting circuit configured to receive or transmit a communication signal via the filter circuit,
the filter circuit being configured to attenuate frequency components of a target band including the first frequency and the second frequency and being included in the communication signal.
